(19) United States
(12) Patent Application Publication
(10) Pub. No.: US 2018/0097468 A1
(43) Pub. Date: Apr. 5, 2018

(54) METHOD OF MANUFACTURING A PHOTOVOLTAIC-THERMOELECTRIC HYBRID DEVICE, AND PHOTOVOLTAIC-THERMOELECTRIC HYBRID DEVICE

(71) Applicant: National Chi Nan University, Nantou County (TW)

(72) Inventors: KUEI-SEN HSIAO, Nantou County (TW); ZHAO-YANG CAI, Nantou County (TW); SHENG-LIN ZHENG, Nantou County (TW); JIN-KAI ZHANG, Nantou County (TW)

(21) Appl. No.: 15/834,912

(22) Filed: Dec. 7, 2017

Related U.S. Application Data
(63) Continuation-in-part of application No. 14/818,381, filed on Aug. 5, 2015, now abandoned.

(30) Foreign Application Priority Data
Jan. 7, 2015 (TW) 104100385

(51) Int. Cl. H02S 10/30; H01L 35/32; H01L 35/22; H01L 35/34; H01L 31/02; H01L 31/0224; H01L 31/028; H01L 31/18

(52) U.S. Cl. CPC H02S 10/30; H01L 35/32; H01L 35/22; H01L 31/1804; H01L 31/02016; H01L 31/0224; H01L 31/0284; H01L 35/34

(57) ABSTRACT

A photovoltaic-thermoelectric hybrid device is disclosed, which comprises a bi-layer silicon substrate, an electrode unit having a first electrode and a second electrode disposed on and connected to the bi-layer silicon substrate, and an external circuit connecting to the electrode unit, in which an electric current is set up between the first electrode and the second electrode and flows through the bi-layer silicon substrate as the first electrode is either heated or illuminated more than the second electrode.

### CROSS-REFERENCE TO RELATED APPLICATION

This application continues in part from U.S. patent application Ser. No. 14/818,381, filed Aug. 5, 2015, which claims priority of Taiwanese Patent Application No. 104100385, filed on Jan. 7, 2015. Both of which are hereby incorporated by reference in their entirety for all purposes.

### FIELD

The disclosure relates to a method of a manufacturing a photovoltaic-thermoelectric hybrid device, and a photovoltaic-thermoelectric hybrid device.

### BACKGROUND

A conventional thermoelectric device includes at least one thermoelectric unit including a P-type semiconductor element and a N-type semiconductor element connected to the P-type semiconductor element. When a temperature difference is presented between the P-type and N-type semiconductor elements, current flow is generated in the conventional thermoelectric device. FIGS. 1 and 2 illustrate consecutive steps of manufacturing a conventional thermoelectric device. In FIG. 1, a first module 71 is obtained by forming a plurality of thermally conductive members 74 and a plurality of first thermoelectric members 710 on a second substrate 711 and a first substrate 712. Then, as shown in FIG. 2, a second module 72 is obtained by forming a plurality of second thermoelectric members 720 between a third substrate 722 and a fourth substrate 721. Each of the first and second thermoelectric members 710, 720 includes a P-type semiconductor element and a N-type semiconductor element. After the second module 72 is stacked on the first module 71, the P-type and N-type semiconductor elements in each of the first and second thermoelectric members 710, 720 are electrically connected to each other to obtain the conventional thermoelectric device.

Manufacturing of the conventional thermoelectric device is complicated, time-consuming and costly.

### SUMMARY

Therefore, an object of the disclosure is to provide a method of manufacturing a photovoltaic thermoelectric hybrid device, and a photovoltaic-thermoelectric hybrid device made therefrom, that can alleviate at least one of the drawbacks associated with the conventional thermoelectric device.

According to a first aspect of the present disclosure, a photovoltaic-thermoelectric hybrid device is provided, which comprises a bi-layer silicon substrate, having a silicon base layer with a nanostructure and a plurality of isolated silicon islands formed on said silicon base layer, wherein a first non-PN junction is formed between said silicon base layer and said silicon islands; an electrode unit that is disposed on and connected to said bi-layer silicon substrate, having a first electrode and a second electrode separated from said first electrode, wherein a second non-PN junction is formed between said electrode unit and said bi-layer silicon substrate; and an external circuit connecting to said electrode unit; wherein an electric current is set up between said first electrode and said second electrode across said first and said second non-PN junction and flows through said bi-layer silicon substrate as said first electrode is either heated or illuminated more than said second electrode.

A second aspect of the present disclosure provides a method of manufacturing a photovoltaic-thermoelectric hybrid device including the steps of:

preparing a silicon substrate and an etching solution that includes hydrofluoric acid, isopropyl alcohol and deionized water, in which a volume ratio of the hydrofluoric acid, isopropyl alcohol and deionized water in the etching solution is 1:2:1 or 1:3:1;

performing electrochemical etching of the silicon substrate in the etching solution to obtain a porous bi-layer silicon substrate having a silicon base layer with a nano structure and a plurality of isolated silicon islands formed on said silicon base layer, wherein a first non-PN junction is formed between said silicon base layer and said silicon islands; and

forming an electrode unit on the porous bi-layer silicon substrate and that is adapted for being connected to an external circuit, the electrode unit has a first electrode and a second electrode separated from said first electrode, wherein a second non-PN junction is formed between said electrode unit and said porous bi-layer silicon substrate.

According to a second aspect of the present disclosure, a photovoltaic-thermoelectric hybrid device includes a porous bi-layer silicon substrate and an electrode unit. The electrode unit is disposed on and connected to the porous bi-layer silicon substrate, and is adapted for being connected to an external circuit.

### BRIEF DESCRIPTION OF THE DRAWINGS

Other features and advantages of the present disclosure will become apparent in the following detailed description of the embodiments with reference to the accompanying drawings, of which:

FIGS. 1 and 2 illustrate consecutive steps of manufacturing a conventional thermoelectric device;

FIG. 3 is a flow chart that illustrates the embodiment of a method of manufacturing a photovoltaic-thermoelectric hybrid device of the present disclosure;

FIG. 4 is a top view of a first embodiment of a photovoltaic-thermoelectric hybrid device of the present disclosure;

FIG. 5A is a top view of a second embodiment of the photovoltaic-thermoelectric hybrid device of the present disclosure;

FIG. 5B is a cross-sectional view of A-A in FIG. 5A;

FIG. 6 is a schematic and partly cross-sectional view of an electrochemical etching apparatus used for manufacturing the photovoltaic-thermoelectric hybrid device of the present disclosure; and

FIG. 7 is a top view showing the photovoltaic-thermoelectric hybrid device of the present disclosure connected to an ammeter.

FIG. 8 are surface (left) and cross-sectional (right)surface SEM images of bi-layer silicon substrate etched with (a) HF:ethanol=1:1 and (b)HF:IPA:DI water=1:2:1 for 30 minutes.

FIG. 9 are SEM images of bi-layer silicon substrate etched with the etching time of (a) 40 minutes and (b) 50 minutes, and the etching current density was fixed at 30 mAcm⁻².

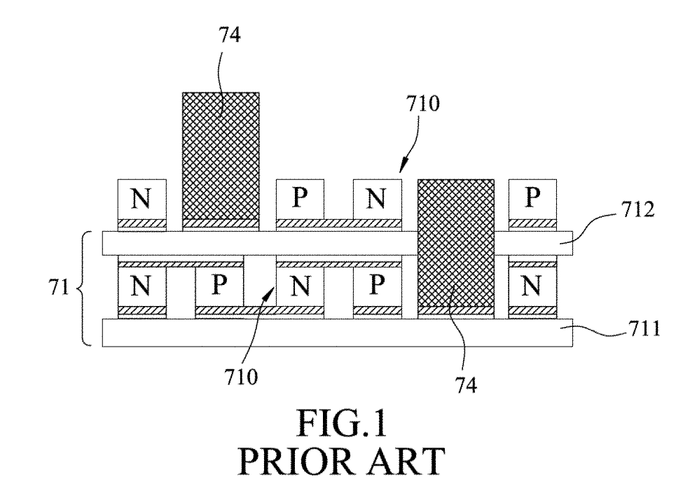

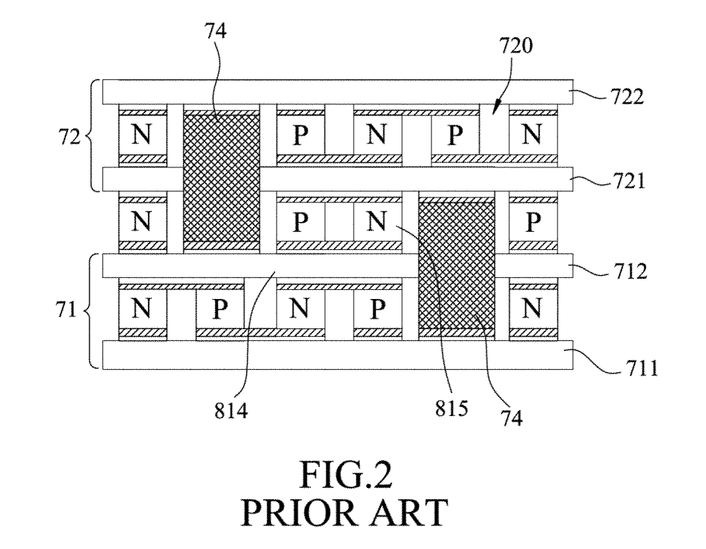

### DETAILED DESCRIPTION

Before the present disclosure is described in greater detail with reference to the accompanying embodiments, it should be noted herein that like elements are denoted by the same reference numerals throughout the disclosure.

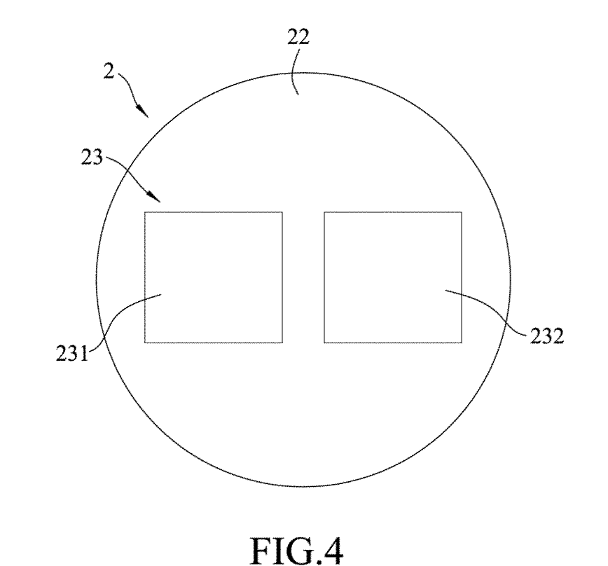

FIG. 4 illustrates a first embodiment of a photovoltaic-thermoelectric hybrid device 2 of the present disclosure. The photovoltaic-thermoelectric hybrid device 2 includes a bi-layer silicon substrate 22 and an electrode unit 23 that is disposed on and connected to the bi-layer silicon substrate 22, and that is adapted for being connected to an external circuit for measuring photoelectric and thermoelectric effects of the sensor 2. The electrode unit 23 includes a first electrode 231 and a second electrode 232 spaced apart from the first electrode 231.

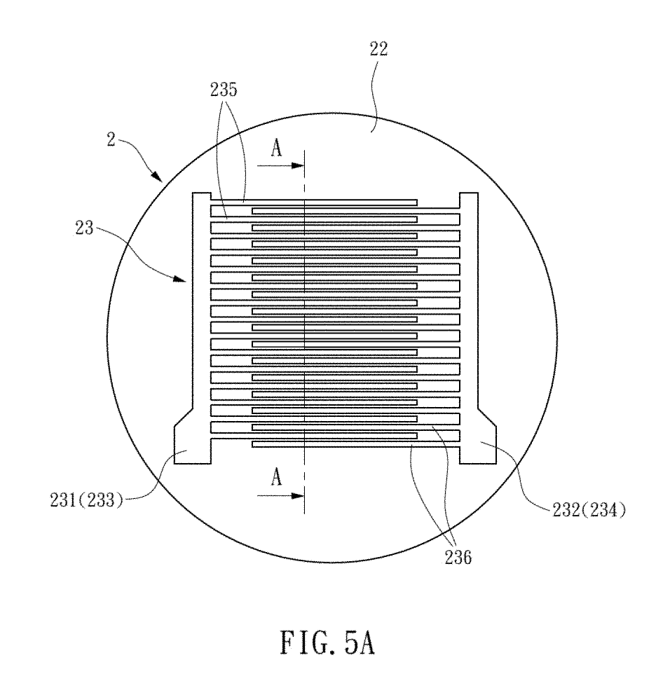

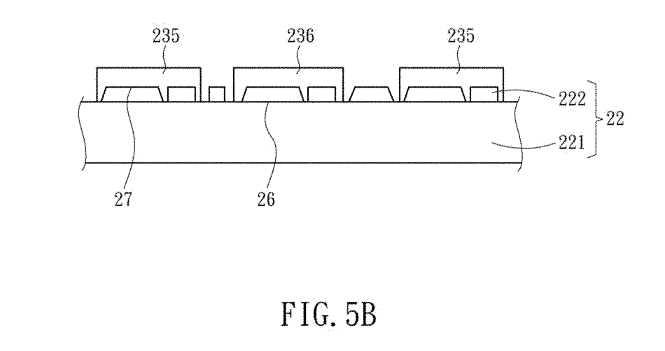

Referring to FIG. 5A, in a second embodiment of the photovoltaic-thermoelectric hybrid device 2, the electrode unit 23 may be configured as an interdigitated electrode structure. The first electrode 231 has a first main portion 233 and a plurality of first protruding portions 235 extending from the first main portion 233 toward the second electrode 232. The second electrode 232 has a second main portion 234 spaced apart from the first main portion 233, and a plurality of second protruding portions 236 extending from the second main portion 234 toward the first electrode 231 and alternately disposed with the first protruding portions 235. Therefore, the first and second electrodes 231, 232 are arranged in an interdigitated comb structure.

To take a closer look at the structure of the photovoltaic-thermoelectric hybrid device, a cross-sectional view of A-A in FIG. 5A is shown as FIG. 5B. The bi-layer silicon substrate 22 has a silicon base layer 221 with a nanostructure and a plurality of isolated silicon islands 222 formed on a top side of the silicon base layer 221, in which the “nanostructure” of the silicon base layer 221 comprises nanopores, nanocrystalline, or a combination thereof. A first non-PN junction 26 is formed between the silicon base layer 221 and the isolated silicon islands 222.

The electrode unit 23 is disposed on the bi-layer silicon substrate 22 and a second non-PN junction 27 is formed between the electrode unit 23 and the bi-layer silicon substrate 22. The electrode unit 23 is connected to the bi-layer silicon substrate 22, in which the first protruding portions 235 and the second protruding portions 236 of the electrode unit 23 respectively cover parts of the silicon base layer 221 and the isolated silicon islands 222 so as to connect the bi-layer silicon substrate 22 through a direct contact.

Such structure has the ability to generate thermal currents and/or photocurrents for the following reasons. First of all, by quantum confinement effect of the nanostructure, the conductivity in the silicon base layer 221 has been improved. Second, the discontinuous distribution of the isolated silicon islands 222 causes a decrease in conductivity, thereby generating a temperature difference and producing photocurrents as well.

In order to decrease contact resistance, the electrode unit 23 may be made of gold. The bi-layer silicon substrate 22 may be a p-type silicon substrate. In this embodiment, the bi-layer silicon substrate 22 is a p-type silicon substrate with a thickness of 525±25 μm. A distance between each of the first protruding portions 235 of the first electrode 231 and an adjacent one of the second protruding portions 236 of the second electrode 232 is not greater than 0.6 mm.

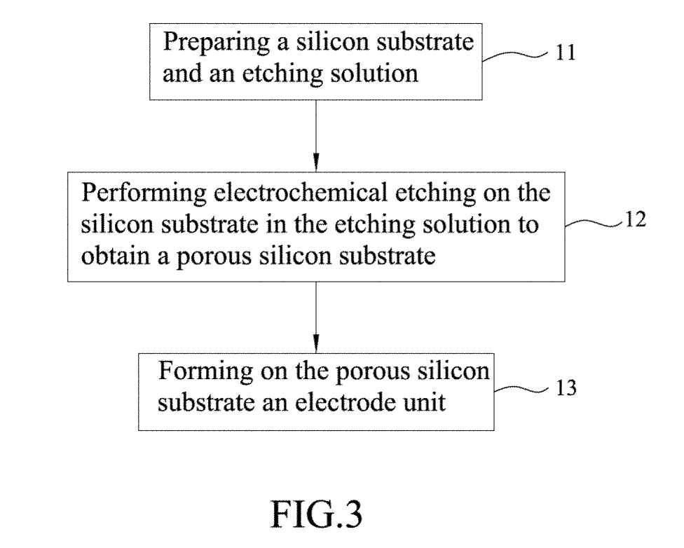

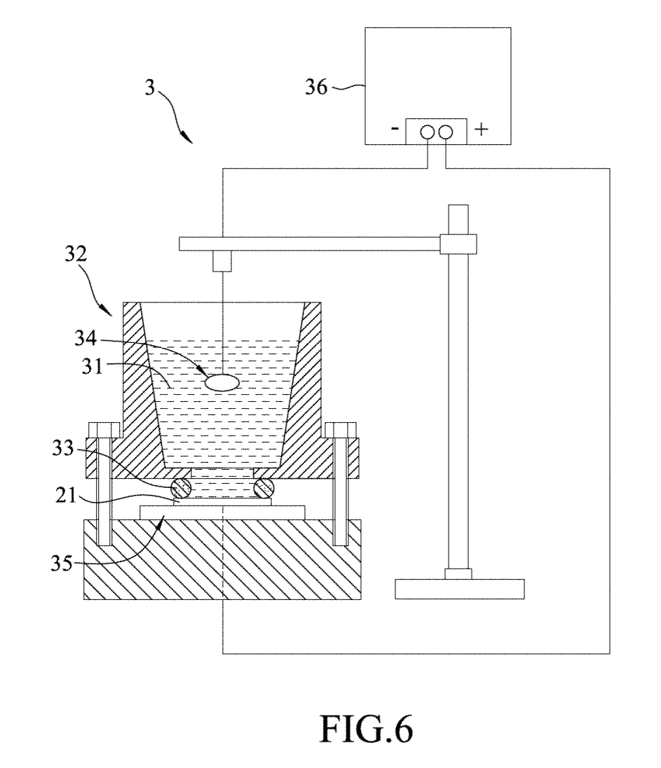

Referring to FIGS. 3 and 6, a method of manufacturing the photovoltaic-thermoelectric hybrid device 2 includes the steps of:

preparing a silicon substrate 21 and an etching solution 31 that includes hydrofluoric acid, isopropyl alcohol and deionized water;

performing electrochemical etching on the silicon substrate 21 in the etching solution to obtain a bi-layer silicon substrate 22; and

forming an electrode unit 23 on the bi-layer silicon substrate 22 and that is connected to the bi-layer silicon substrate 22 and that is adapted for being connected to the external circuit.

To be more specific, an electrochemical etching apparatus 3 (see FIG. 6) is used for etching the silicon substrate 21 to obtain the bi-layer silicon substrate 22, and includes a reaction vessel 32 that is for receiving the etching solution 31 and that is formed with a bottom opening, an O-ring 33 that is disposed underneath the bottom opening, a cathode 34, an anode 35 and a power supply 36. The reaction vessel 32 and the O-ring 33 may be made of polytetrafluoroethylene (also known as Teflon), which is resistant to acid, base, corrosion, and is insoluble in and non-reactive with the etching solution 31. The cathode 34 and the anode 35 are made of conductive materials. The cathode 34 may be made of copper, and the anode 35 may be made of platinum.

The silicon substrate 21 is fixed between the anode 35 and the O-ring 33. The O-ring 33 hermetically seals a gap between the silicon substrate 21 and the reaction vessel 32. The etching solution 31 is added into the reaction vessel 32 and the cathode 34 is then dipped into the etching solution 31. The silicon substrate 21 is electrochemically etched under the conditions that the current density of the power supply 36 is ranged from 30 to 50 mA/cm² and the temperature of the etching solution 31 is ranged from 20° C. to 40° C. Note that the current density may be altered according to practical requirements. The electrochemical etching is performed for 20 minutes to 50 minutes. For example, the electrochemical etching may be performed for 20 minutes, 30 minutes, 40 minutes, or 50 minutes. During the electrochemical etching process, a reduction reaction producing hydrogen ions take places at the cathode 34 so as to release hydrogen gas, and an oxidation reaction takes place at the anode 35 such that the silicon substrate 21 contacting the anode 35 is etched to form the bi-layer silicon substrate 22. The bi-layer silicon substrate 22 has a silicon base layer 221 with pore sizes ranging from 10 nm to 100 nm, and a plurality of isolated silicon islands 222 formed on a top side of the silicon base layer 221 A first non-PN junction 26 is formed between the silicon base layer 221 and the isolated silicon islands 222.

It should be noted that shapes of the pores of the the silicon base layer 221 may change with the concentration and composition ratio of the etching solution 31. Isopropyl alcohol (IPA) is used to reduce etching rate and increase etching uniformity to obtain the silicon base layer 221 having finer and more evenly distributed pores. A volume ratio of hydrofluoric acid to isopropyl alcohol to deionized water in the etching solution 31 is 1:2:1 or 1:3:1.

Preferably, before etching, the silicon substrate 21 is ultrasonically washed with deionized water, acetone and ethanol in sequence and is then blow-dried with nitrogen.

The electrode unit 23 formed on the bi-layer silicon substrate 22 may be the one shown in FIG. 4 or the one shown in FIG. 5 (i.e., the interdigitated electrode unit 23) and a second non-PN junction 27 is formed between the electrode unit 23 and the bi-layer silicon substrate 22.

To form the interdigitated electrode unit 23 on the bi-layer silicon substrate 22, thermal evaporation deposition with the use of a shadow mask is used so as to deposit the interdigitated electrode unit 23 onto the bi-layer silicon substrate 22. To be more specific, the shadow mask with a pattern corresponding to the pattern of the interdigitated electrode unit 23 is laminated on the bi-layer silicon substrate 22. Gold is evaporated under vacuum, and is deposited on the bi-layer silicon substrate 22 so as to form the interdigitated electrode unit 23 on the bi-layer silicon substrate 22. The thickness of the interdigitated electrode unit 23 may be 50 nm and can be changed according to practical requirements.

The following examples and comparative examples are provided to illustrate the embodiments of the disclosure, and should not be construed as limiting the scope of the disclosure.

### EXAMPLES

### Example 1 (E1)

A photovoltaic-thermoelectric hybrid device 2 having the structure shown in FIG. 4 was prepared based on the method of the present disclosure under the following conditions. The volume ratio of hydrofluoric acid (HF) to isopropyl alcohol (IPA) to deionized water in the etching solution 31 was 1:3:1. The current density of the power supply 36 was set at 50 mA/cm². The temperature of the etching solution 31 was maintained in the range of 20° C. to 40° C. The electrochemical etching was conducted for 30 minutes. Each of the first and second electrodes 231, 232 had a length of 4 mm and a width of 4 mm. A distance between the first and second electrodes 231, 232 was 1.5 mm.

### Example 2 (E2)

A photovoltaic-thermoelectric hybrid device 2 having the structure shown in FIG. 5 was prepared based on the method of the present disclosure under the following conditions. The volume ratio of hydrofluoric acid to isopropyl alcohol to deionized water in the etching solution 31 was 1:2:1. The current density of the power supply 36 was set at 50 mA/cm². The temperature of the etching solution 31 was maintained in the range of 20° C. to 40° C. The electrochemical etching was conducted for 30 minutes. The electrode unit 23 having a thickness of 0.1 mm was prepared using thermal evaporation deposition. Each of the first and second main portions 233, 234 had a length of 9 mm and a width of 1 mm. Each of the first and second protruding portions 235, 236 had a length of 6 mm and a width of 0.1 mm. The distance between each of the first protruding portions 235 and an adjacent one of the second protruding portions 236 was 0.14 mm.

### Example 3 (E3)

The photovoltaic-thermoelectric hybrid device 2 of Example 3 was similar in structure to that of Example 2, except that the distance between each of the first protruding portions 235 and an adjacent one of the second protruding portions 236 was 0.6 mm.

### Example 4 (E4)

The method for forming the photovoltaic thermoelectric hybrid device 2 of Example 4 was similar to that of Example 2, except that the volume ratio of hydrofluoric acid to isopropyl alcohol to deionized water in the etching solution 31 was 1:2:1. The structure of the photovoltaic-thermoelectric hybrid device thus obtained was similar to that of Example 2, except that the distance between each of the first protruding portions 235 and an adjacent one of the second protruding portions 236 was 0.6 mm.

### Comparative Example (CE)

The method for forming the photovoltaic-thermoelectric hybrid device of Comparative Example was similar to that of Example 4, except that the etching solution was composed of hydrofluoric acid (HF) and ethanol (EtOH) at a volume ratio of 1:1.

### Determination of Thermoelectric Property

The thermoelectric property of the photovoltaic-thermoelectric hybrid device 2 of Example 2 was determined.

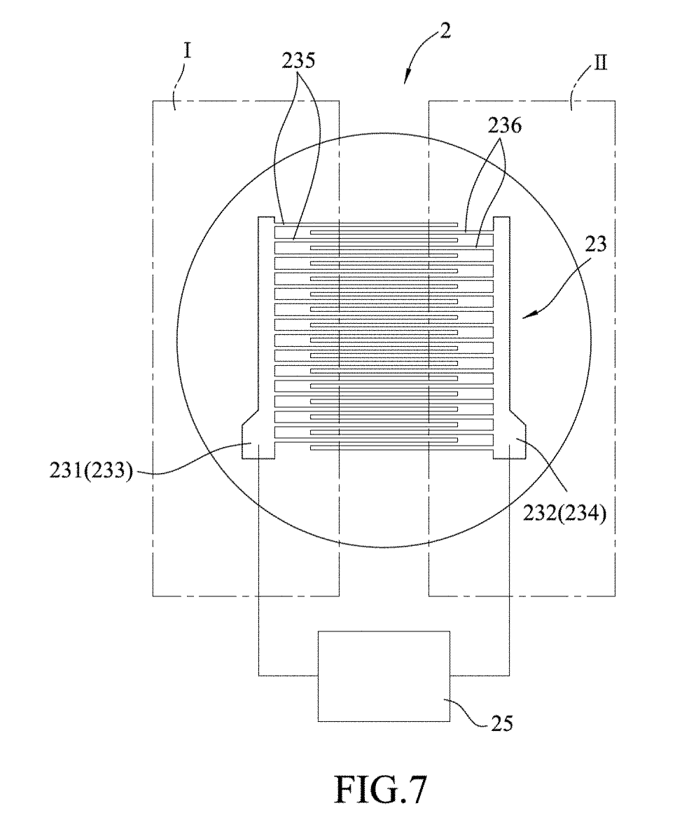

Specifically, referring to FIG. 7, a first region I surrounding the first main portion 233 of the first electrode 231 and part of the first protruding portions 235, and a second region II surrounding the second main portion 234 of the second electrode 232 and part of the second protruding portions 236 were defined. The first and second main portions 233, 234 were connected to an ammeter 25. One of the first and second regions I, II was heated (e.g., the first region I was heated and the second region II was not heated) to measure the current generated by the photovoltaic-thermoelectric hybrid device 2.

During the heating process, temperature differences between the first and second main portions 233, 234, and corresponding current flows were recorded as shown in Table 1.

TABLE 1

| Temperature Difference (° C.) | Current flow (μA) |
|---|---|
| 0 | 0.186 |
| 0.4 | 6.86 |
| 0.6 | 7.50 |

As shown in Table 1, the photovoltaic-thermoelectric hybrid device 2 of E2 is capable of producing current flow in response to the temperature difference between the first and second electrodes 231, 232. The current flow increased with an increase of the temperature difference.

### Determination of Photoelectric Property

Similar to the procedure in Determination Of Thermoelectric Property, in each of the photovoltaic-thermoelectric hybrid device of E1 to E4 and CE, a first region I and a second region II were defined. The first and second electrodes 231, 232 respectively in the first and second regions I, II of the photovoltaic-thermoelectric hybrid device of E1 were connected to an ammeter 25. Similarly, the first and second main portions 233, 234 in each of the photovoltaic-thermoelectric hybrid devices of E2 to E4 and CE were connected to an ammeter 25. In each of the photovoltaic-thermoelectric hybrid devices, the first region I was first illuminated by a light source (e.g. an LED, a laser, etc.). The second region II was then illuminated by the light source. Current flows generated by the photovoltaic-thermoelectric hybrid device were measured by the ammeter 25 and were recorded.

Tables 2 and 3 show the maximum current flow for each of the photovoltaic-thermoelectric hybrid devices.

TABLE 2

| | Electrode Configuration | Current flow (μA) |
|---|---|---|
| Example 1 | Structure shown in | 1.2290 |
| | FIG. 4 | |
| Example 2 | Interdigitated | 0.7065 |
| | electrode structure | |
| | with 0.14 mm distance | |
| Example 3 | Interdigitated | 1.0912 |
| | electrode structure | |
| | with 0.6 mm distance | |

According to Table 2, each of the photovoltaic-thermoelectric hybrid devices 2 of E1 to E4 is capable of transforming light energy into electric energy. Based on the results of the Examples 2 and 3, the current flow increases with an increase in the distance between each of the first protruding portions 235 and an adjacent one of the second protruding portions 236.

TABLE 3

| | Electrode | Etching | Current flow |
|---|---|---|---|
| | Configuration | Solution | (μA) |
| Example 1 | Structure shown in | HF:IPA:DI | 1.2290 |
| | FIG. 4 | water = 1:3:1 | |
| Example 3 | Interdigitated | HF:IPA:DI | 1.0912 |
| | electrode | water = 1:3:1 | |
| | structure with | | |
| | 0.6 mm distance) | | |
| Example 4 | Interdigitated | HF:IPA:DI | 1.1160 |
| | electrode | water = 1:2:1 | |
| | structure with | | |
| | 0.6 mm distance) | | |
| Comparative | Interdigitated | HF:EtOH = 1:1 | 0.1110 |
| Example | electrode | | |
| | structure with | | |
| | 0.6 mm distance) | | |

As shown in Table 3, compared with the sensor of the Comparative Example, the photovoltaic-thermoelectric hybrid devices 2 manufactured by the method of this disclosure (i.e., the Examples 1, 3 and 4) generate higher current flows and have better photoelectric property.

### Parameters Affecting the Morphology of the Silicon Substrate

To examine how parameters of the electrochemical etching affect the morphology of the bi-layer silicon substrate and influence photothermoelectric effect, the morphologies of bi-layer silicon substrates obtained by different etching solution and etching time are observed.

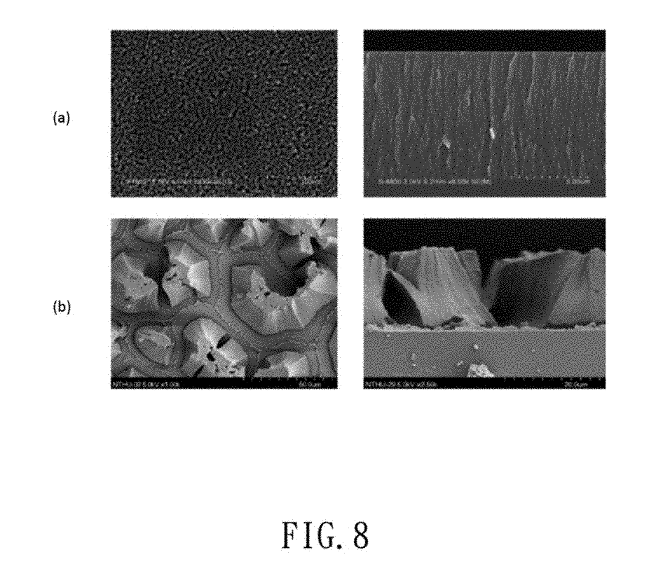

FIG. 8 are surface (left) and cross-sectional (right)surface SEM images of bi-layer silicon substrate etched with (a) HF:ethanol=1:1 and (b)HF:IPA:DI water=1:2:1. Except for the etching current density is fixed at 30 mA/cm², the temperature, the etching time, and the preparation steps are the same as described in the Comparative Example (CE) and the Example 4 (E4), respectively. It can be seen from FIG. 8 that a typical use of ethanol, along with HF for anodized etching of bi-layer silicon substrate, is to eliminate hydrogen bubbles, making the etching process more homogeneous and generating a well-dispersed nanopores inside the silicon substrate. However, the use of IPA facilitates inhomogeneous etching and discontinuous, and thus forms micro-size and island-like shape microstructures in the bi-layer silicon substrate, as shown in (b). The island-like shape microstructures reduce the contact resistance between the electrode and the bi-layer silicon substrate, and the leakage current inside the bi-layer silicon substrate as well, and thus, the island-like shape microstructures play critical roles in the photothermoelectric effect.

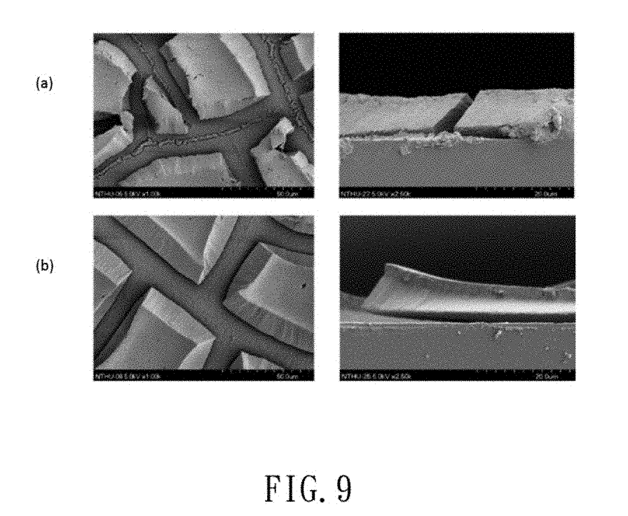

As the etching time increased to (a)40 minutes and (b)50 minutes, respectively, an increased island-like shape microstructures and a decreased etching thickness are observed in the bi-layer silicon substrate (FIG. 9). According to the experiment, the amount of nanoporous reduced with an increase of the etching time whose effect prevents the quantum confinement of the bi-layer silicon substrate and further reduces the electrical conductivity inside the bi-layer silicon substrate, which is disadvantageous.

To sum up, by virtue of the structure of the bi-layer silicon substrate, the photovoltaic-thermoelectric hybrid devices 2 without conventional PN junction could exhibit superior photoelectric and thermoelectric properties. The conventional structure composed of N-type and P-type semiconductor elements can be omitted. The manufacturing process can be simplified and the cost thereof can be reduced.

While the disclosure has been described in connection with what are considered the embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A photovoltaic-thermoelectric hybrid device comprising:
a bi-layer silicon substrate, having a silicon base layer with a nanostructure and a plurality of isolated silicon islands formed on a topside of said silicon base layer, wherein a first non-PN junction is formed between said silicon base layer and said silicon islands;
an electrode unit that is disposed on and connected to said bi-layer silicon substrate, having a first electrode and a second electrode separated from said first electrode, wherein a second non-PN junction is formed between said electrode unit and said bi-layer silicon substrate; and
an external circuit connecting to said electrode unit;
wherein an electric current is set up between said first electrode and said second electrode across said first and said second non-PN junction and flows through said bi-layer silicon substrate as said first electrode is either heated or illuminated more than said second electrode.

2. The photovoltaic-thermoelectric hybrid device as claimed in claim 1, wherein said electrode unit is made of gold.

3. The photovoltaic-thermoelectric hybrid device as claimed in claim 1, wherein said first electrode has a first main portion and a plurality of first protruding portions extending from said first main portion, while said second electrode has a second main portion spaced apart from said first main portion, and a plurality of second protruding portions extending from said second main portion, said first and second electrodes being arranged in an interdigitated comb structure.

4. The photovoltaic-thermoelectric hybrid device as claimed in claim 3, wherein a distance between one of said first protruding portions and an adjacent one of said second protruding portions is not greater than 0.6 mm.

5. The photovoltaic-thermoelectric hybrid device as claimed in claim 1, wherein said bi-layer silicon substrate is a p-type silicon substrate.

6. The photovoltaic-thermoelectric hybrid device as claimed in claim 1, wherein said electrode unit covers parts of said silicon base layer and said isolated silicon island so as to connect said bi-layer silicon substrate via a direct contact.

7. The photovoltaic-thermoelectric hybrid device as claimed in claim 1, wherein said nanostructure comprises nanopores, nanocrystalline, or a combination thereof.
